(19) United States
(12) Patent Application Publication
(10) Pub. No.: US 2025/0126813 A1
(43) Pub. Date: Apr. 17, 2025

(54) DIELECTRIC LAYERS IN MAGNETIC MOLD COMPOUND INDUCTOR PACKAGES

(71) Applicant: TEXAS INSTRUMENTS INCORPORATED, Dallas, TX (US)

(72) Inventors: Sylvester ANKAMAH-KUSI, McKinney, TX (US); Jonathan Almeria NOQUIL, Plano, TX (US); Rajen Manicon MURUGAN, Dallas, TX (US)

(21) Appl. No.: 18/680,535

(22) Filed: May 31, 2024

Related U.S. Application Data
(60) Provisional application No. 63/590,486, filed on Oct. 16, 2023.

(51) Int. Cl. H01F 27/28; H01F 27/32; H01F 41/04; H01F 41/12

(52) U.S. Cl. CPC H10D 1/20; H01F 27/2804; H01F 27/323; H01F 41/041; H01F 41/122; H01F 2027/2809

(57) ABSTRACT

In examples, a semiconductor package comprises a semiconductor die, and an inductor coupled to the semiconductor die. The inductor comprises a first metal coil having a first end coupled to the semiconductor die and a second end; a second metal coil vertically spaced from the first metal coil and having a third end coupled to the second end and a fourth end coupled to the semiconductor die; a magnetic mold compound (MMC) between the first and second metal coils, the MMC including conductive ions; and an insulative layer between the first and metal coils.

### CROSS-REFERENCE TO RELATED APPLICATIONS

The present application claims priority to U.S. Provisional Patent Application No. 63/590,486, which was filed Oct. 16, 2023, is titled “METHOD OF BUILDING HIGH Q INDUCTORS IN SUBSTRATES WITH MMC,” and is hereby incorporated herein by reference in its entirety.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. An individual die is then coupled to a die pad and to conductive terminals, sometimes called “leads.” The resulting structure is subsequently covered with a mold compound to produce a package.

### SUMMARY

In examples, a semiconductor package comprises a semiconductor die, and an inductor coupled to the semiconductor die. The inductor comprises a first metal coil having a first end coupled to the semiconductor die and a second end; a second metal coil vertically spaced from the first metal coil and having a third end coupled to the second end and a fourth end coupled to the semiconductor die; a magnetic mold compound (MMC) between the first and second metal coils, the MMC including conductive ions; and an insulative layer between the first and metal coils.

In examples, a method for manufacturing a semiconductor package comprises plating a first metal coil on a carrier; covering the first metal coil with a first magnetic mold compound (MMC) layer; grinding the first MMC layer to reduce a thickness of the first MMC layer; covering the first MMC layer with an insulative layer having a thickness ranging from 10 microns to 40 microns; forming first and second orifices in the insulative layer; plating a second metal coil on a first surface of the insulative layer opposite a second surface of the insulative layer facing the first metal coil, the first and second metal coils coupled by a via extending through the first orifice; covering the second metal coil with a second MMC layer; grinding the second MMC layer to reduce a thickness of the second MMC layer; removing the carrier; coupling a semiconductor die to the first and second metal coils; and covering the semiconductor die and the first and second metal coils with a mold compound.

### BRIEF DESCRIPTION OF THE DRAWINGS

FIGS. 1A1-1L3 are profile, top-down, and perspective views of a process flow for manufacturing a magnetic mold compound (MMC) inductor package having dielectric layers, in accordance with various examples.

FIG. 2 is a flow diagram of a method for manufacturing a semiconductor package including an MMC inductor package having dielectric layers, in accordance with various examples.

FIGS. 3A-3C are perspective, top-down, and profile views of coils and vias in an MMC inductor package having dielectric layers, in accordance with various examples.

FIGS. 4A-4C are perspective, top-down, and profile views of an MMC inductor package having dielectric layers, in accordance with various examples.

FIGS. 5A-5C are profile cross-sectional, top-down, and perspective views of a semiconductor package including an MMC inductor package having dielectric layers, in accordance with various examples.

### DETAILED DESCRIPTION

Semiconductor packages generally include semiconductor dies. Some semiconductor packages may include components in addition to semiconductor dies. For example, some packages may include passive components, such as inductors. In packages containing inductors, one or more metal coils may couple to a semiconductor die that uses the one or more metal coils as part of a circuit. Further, some inductor packages may include specialized types of mold compounds, such as magnetic mold compounds (MMCs). MMCs use ferromagnetic particles like iron or ferrite to manage magnetic flux, enhancing efficiency. MMCs act as shields against electromagnetic interference, protecting adjacent components and reducing external interference. They also dissipate heat and provide mechanical support, improving inductor reliability in electronic circuits.

Some types of inductor packages are manufactured using an iterative process in which a coil is formed, an MMC layer is applied to cover the coil, the MMC layer is grinded to reduce the thickness of the MMC layer, and then a second coil is formed on the grinded MMC layer. This technique for manufacturing inductor packages may be disadvantageous because the grinding process mentioned above causes metal ions (e.g., iron ions) in the MMC layer to become exposed. When the second coil is then plated on the MMC, the second coil makes contact with the exposed metal ions, leaving the different portions or segments of the second coil vulnerable to unintended shorting by the metal ions that were exposed by the grinding process. Such electrical shorting renders the inductor package useless. To mitigate the risk of this type of electrical shorting, the coils may be enlarged in the horizontal plane such that the gaps between adjacent segments of a coil are too far apart to be shorted by exposed metal ions. However, this approach undesirably increases package size and manufacturing cost while decreasing manufacturing efficiency. Furthermore, the risk of shorting limits the flexibility of the coil architecture, meaning that additional coil turns may be unachievable without significant increases in electrical shorting risk.

This disclosure describes a semiconductor package manufacturing technique that mitigates the electrical shorting risks described above. In some examples, the semiconductor package manufacturing technique comprises plating a first metal coil on a carrier, covering the first metal coil with a first magnetic mold compound (MMC) layer, and grinding the first MMC layer to reduce a thickness of the first MMC layer. The method also includes covering the first MMC layer with an insulative layer having a thickness ranging from 10 microns to 40 microns, forming first and second orifices in the insulative layer, and plating a second metal coil on a first surface of the insulative layer opposite a second surface of the insulative layer facing the first metal coil. The first and second metal coils are coupled by a via extending through the first orifice. The method further includes covering the second metal coil with a second MMC layer, grinding the second MMC layer to reduce a thickness of the second MMC layer, removing the carrier, and coupling a semiconductor die to the first and second metal coils. The method also comprises covering the semiconductor die and the first and second metal coils with a mold compound. In addition, by mitigating shorting risk without enlarging the coils, package size and manufacturing costs are kept low, and manufacturing efficiency remains high. Further still, the coil geometry is flexible, meaning that the number of coil turns can be freely increased and decreased without increasing the risk of electrical shorts by exposed metal ions.

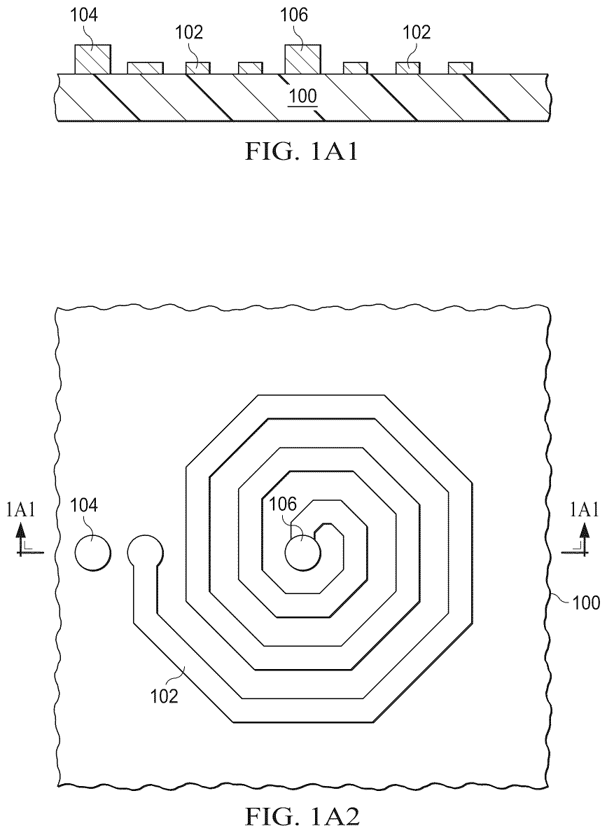

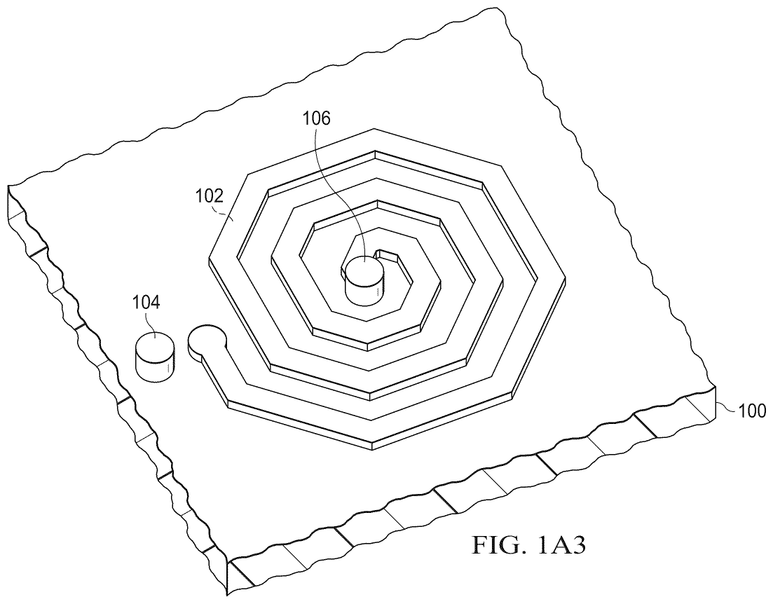

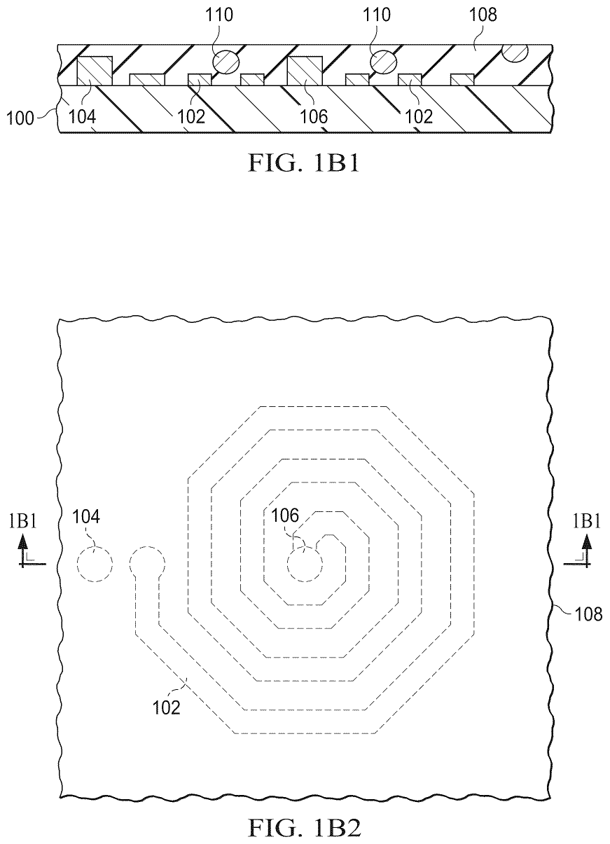

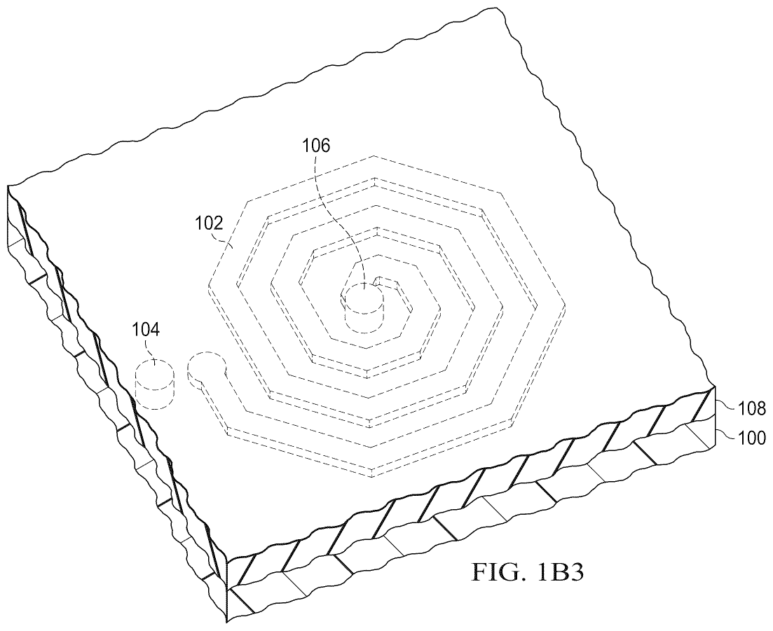

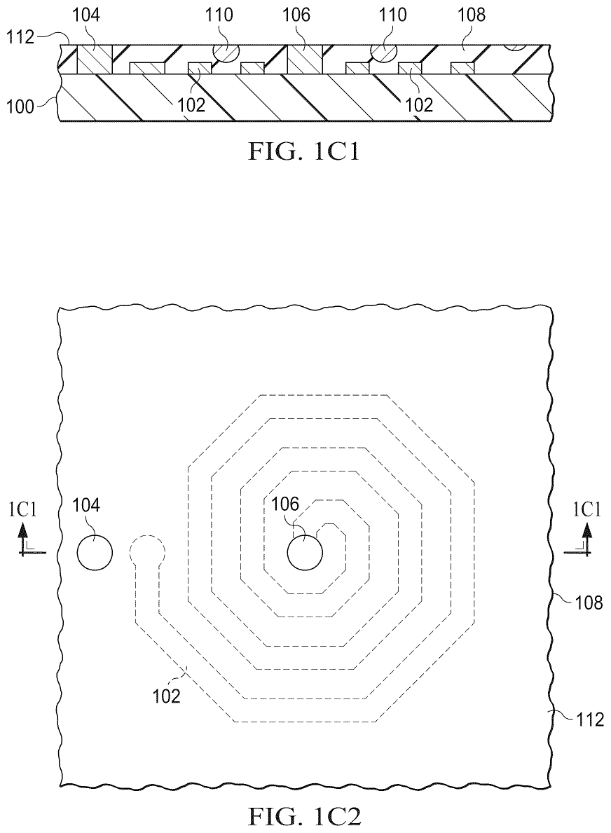

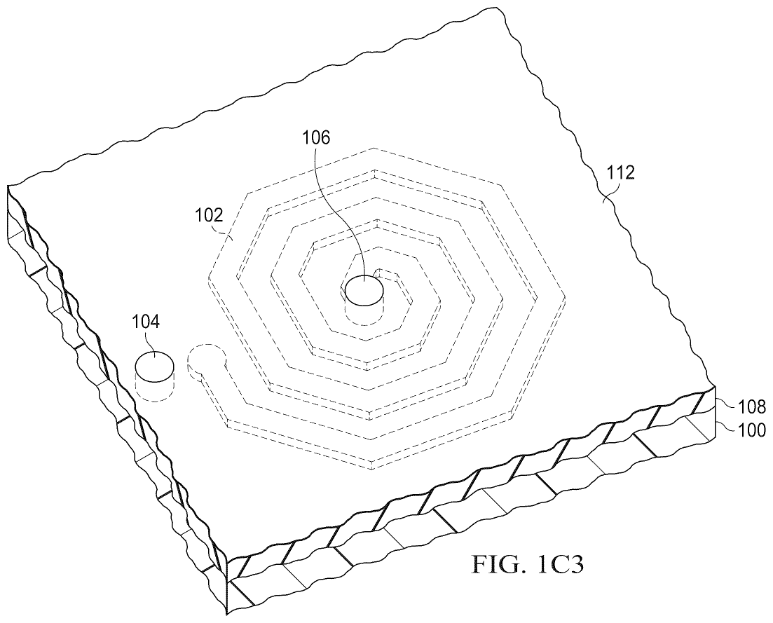

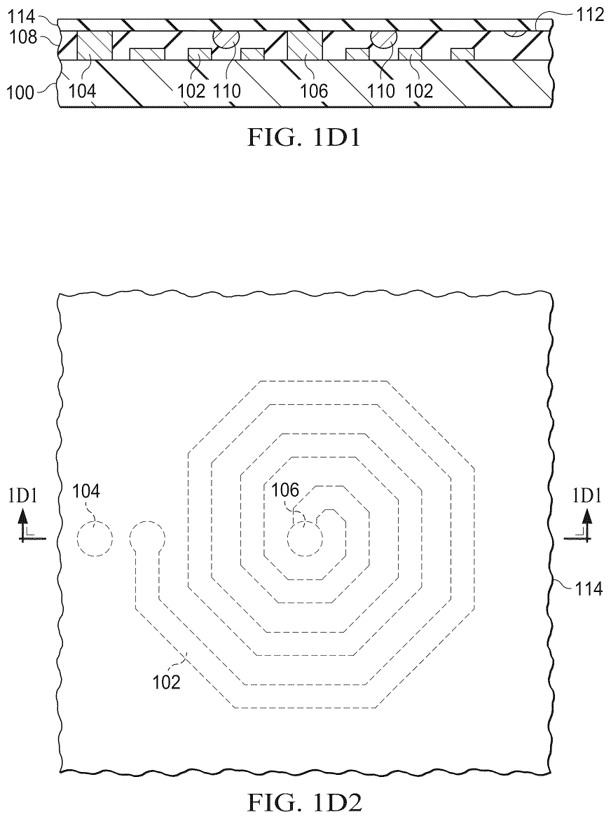

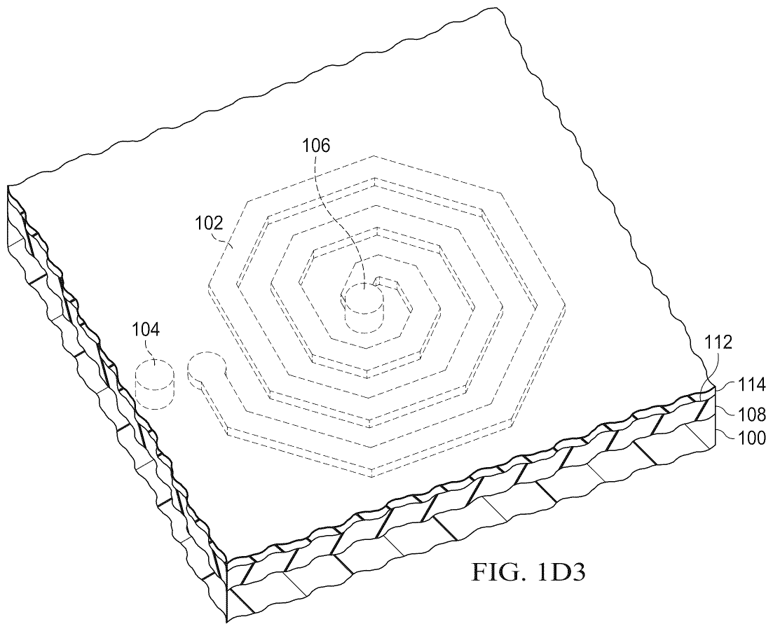

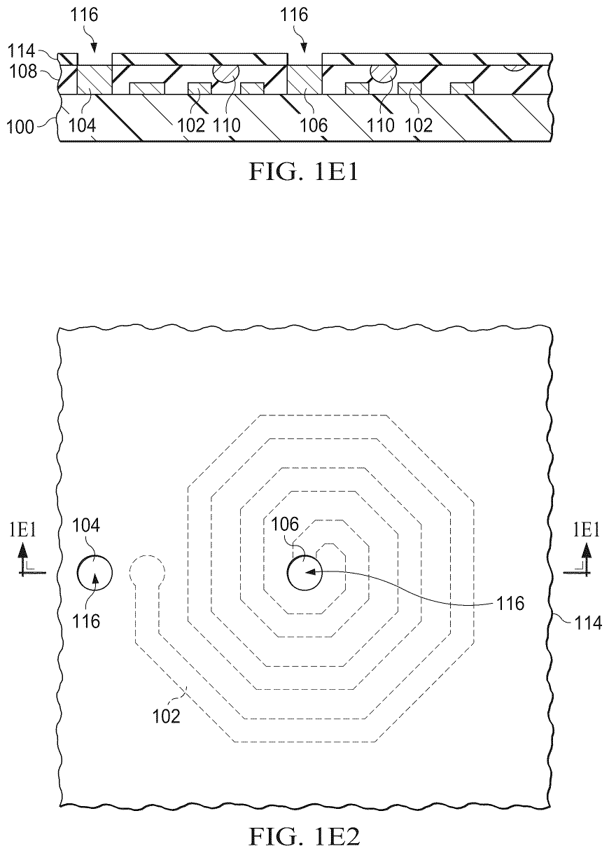

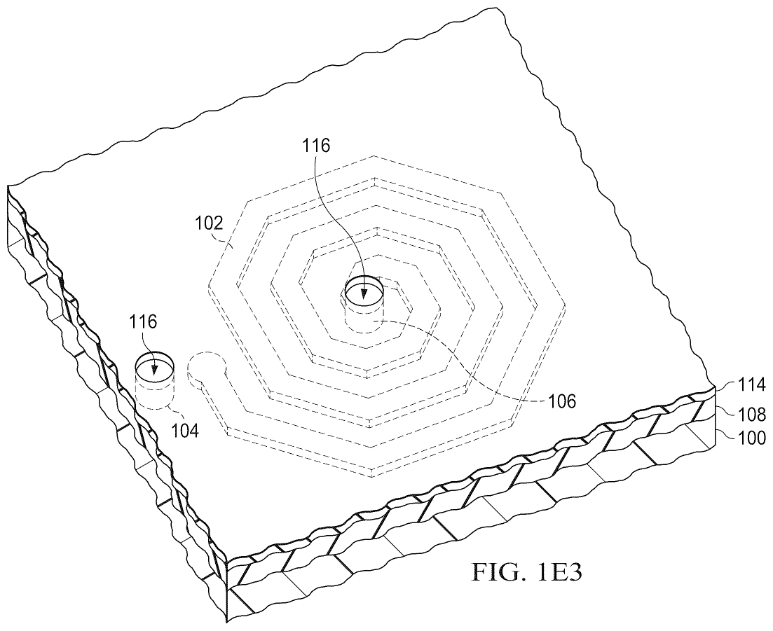

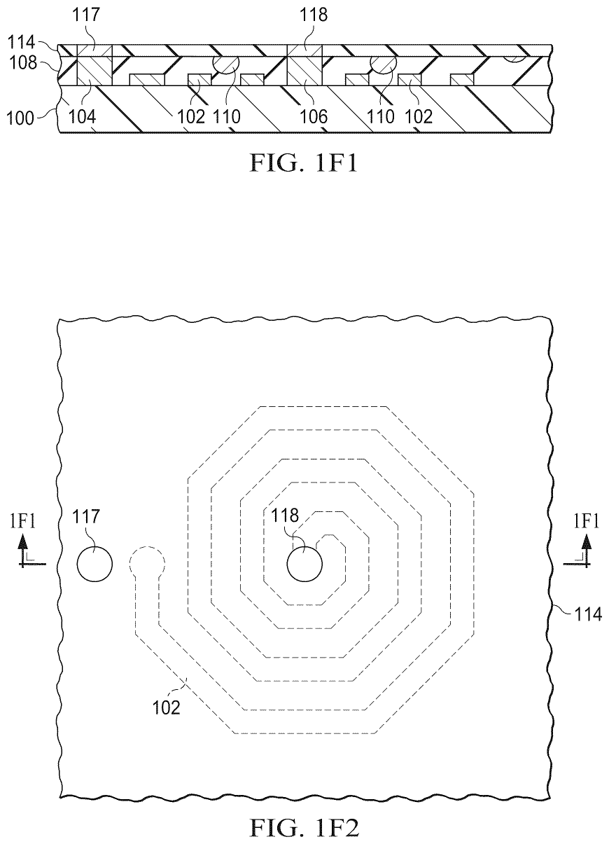

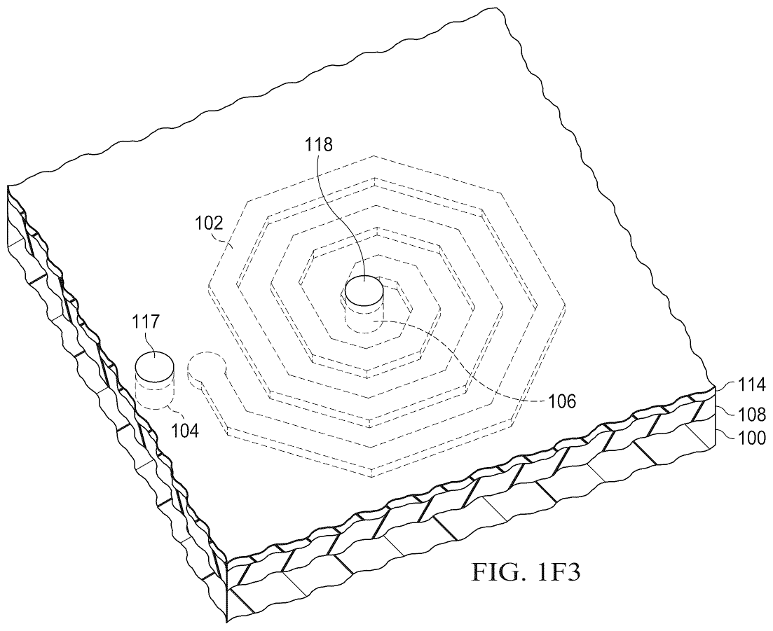

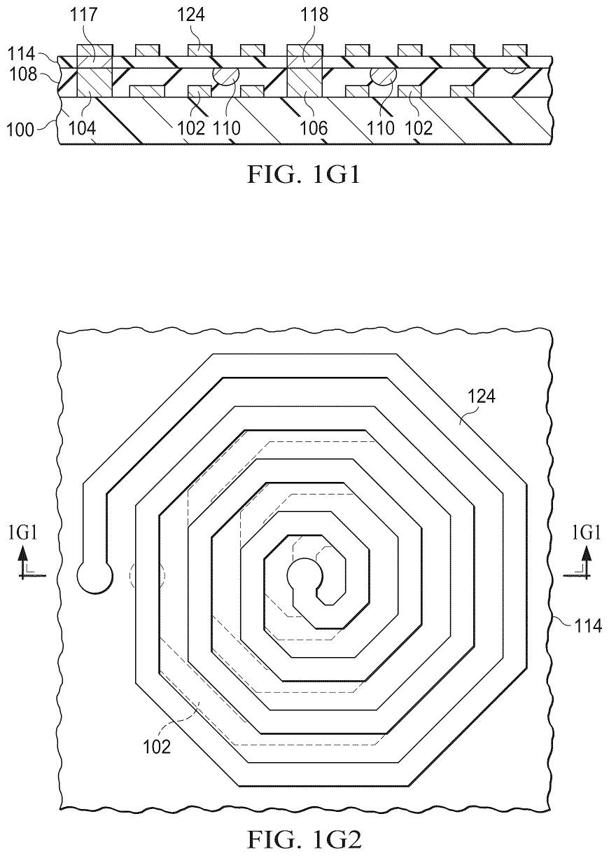

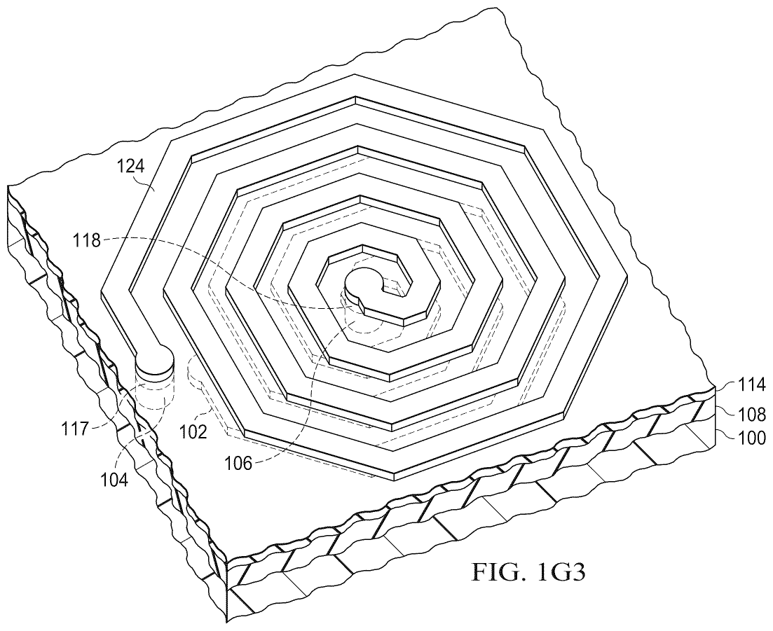

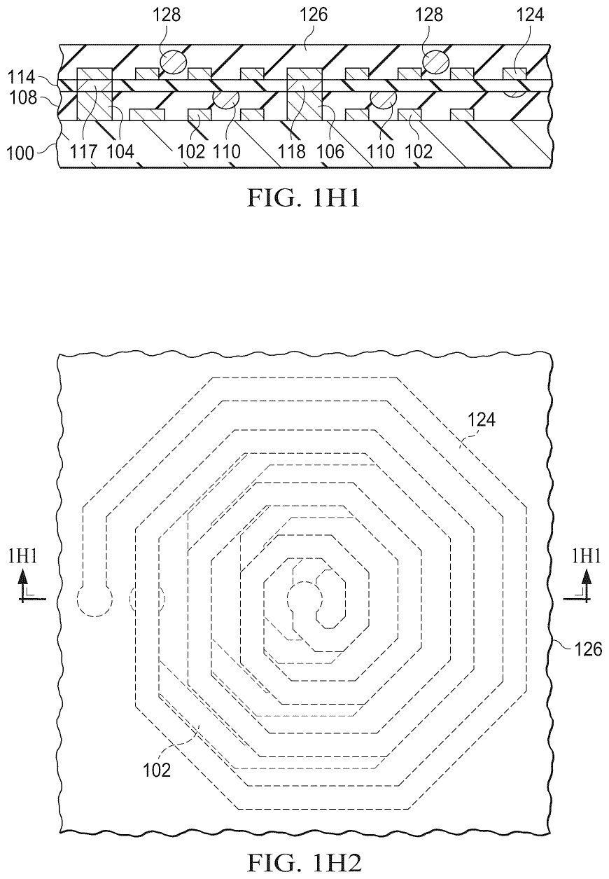

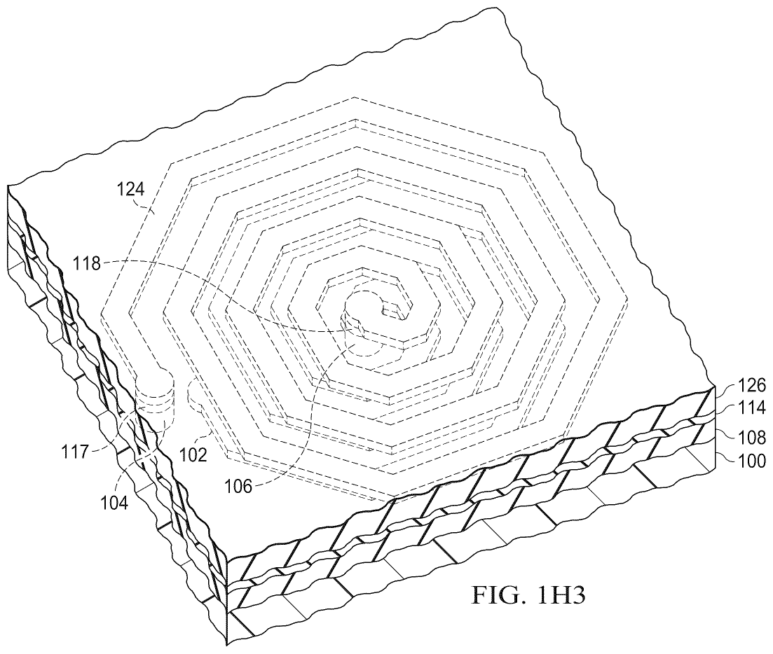

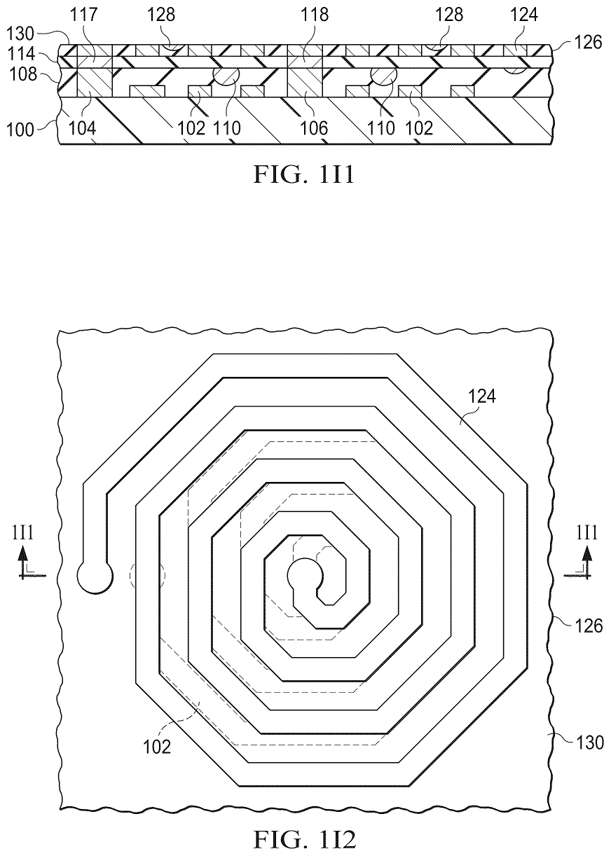

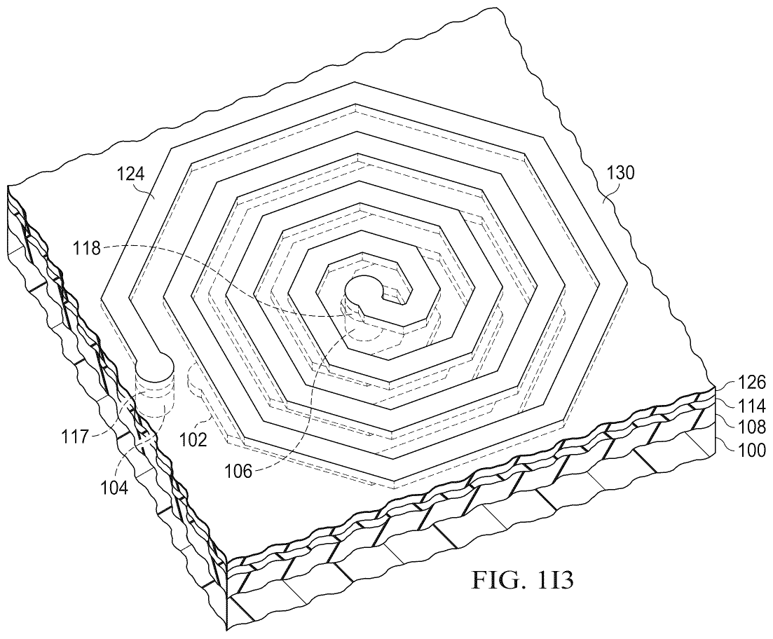

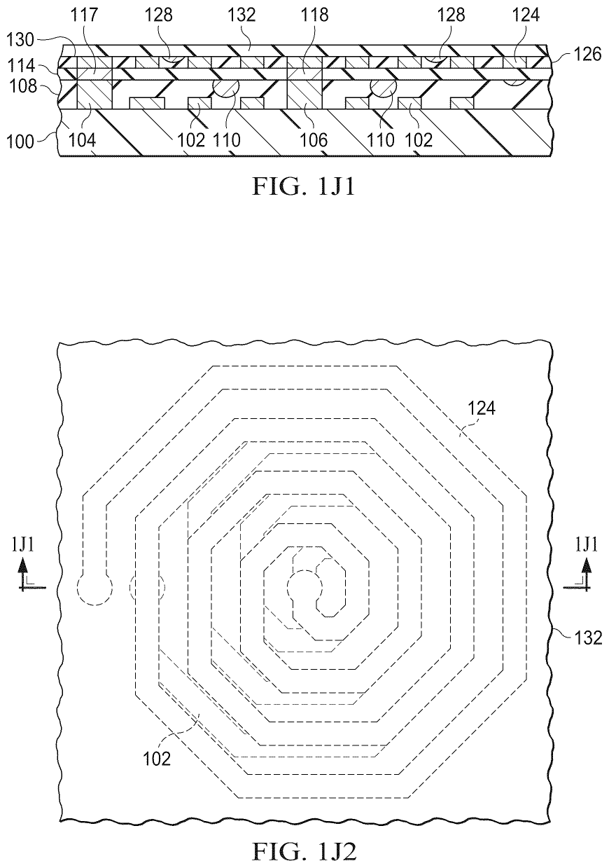

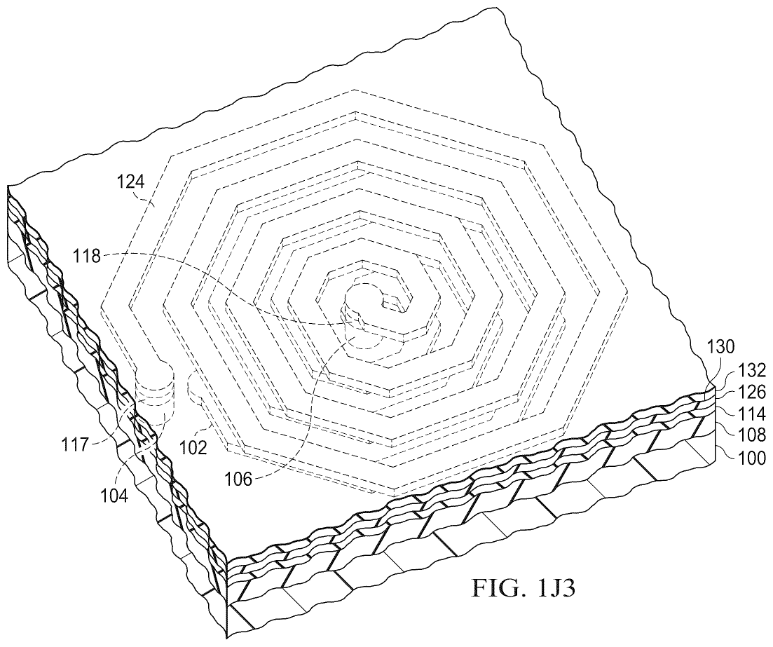

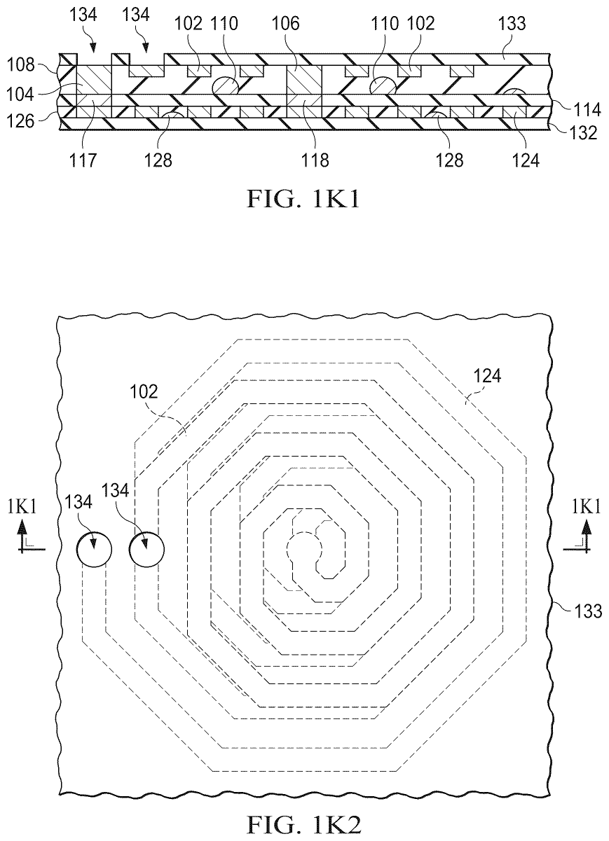

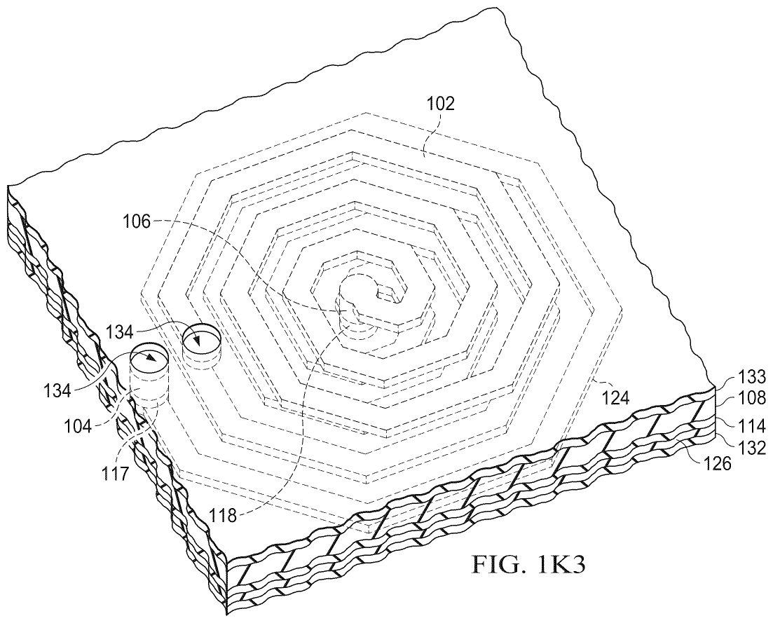

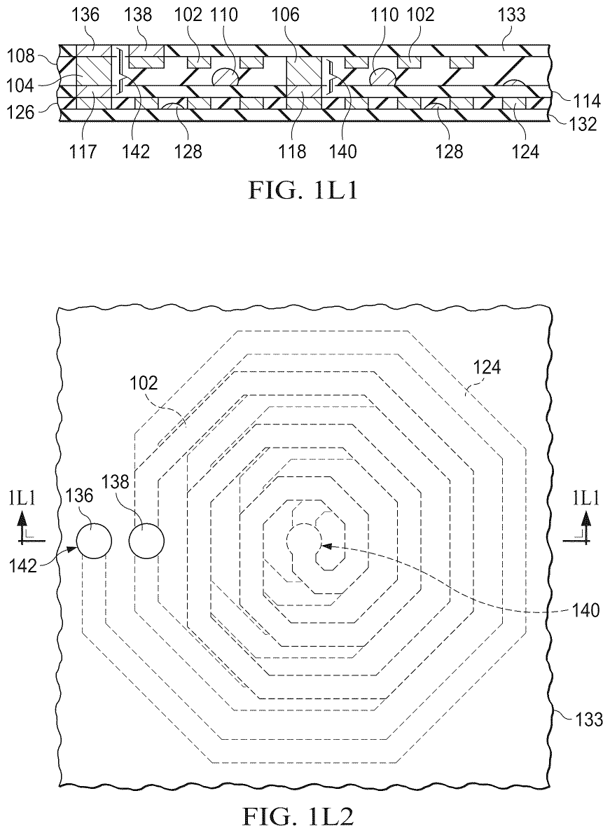

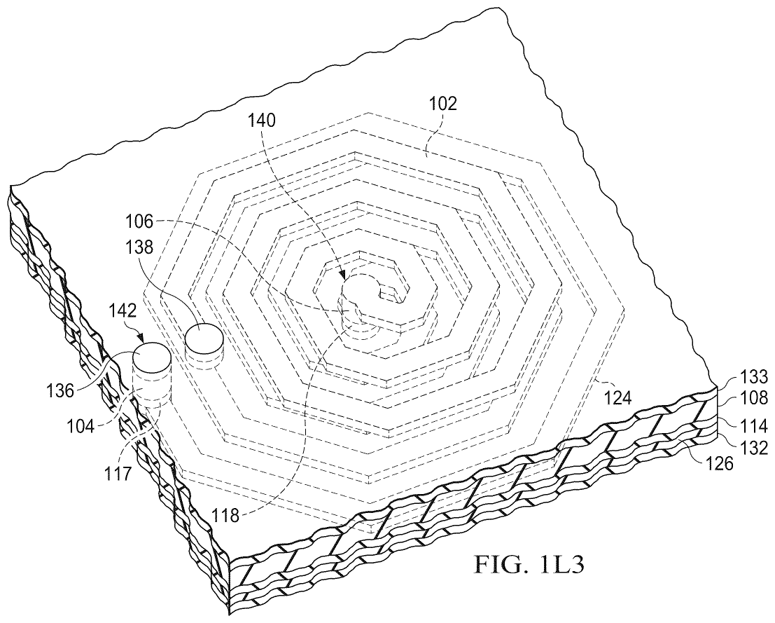

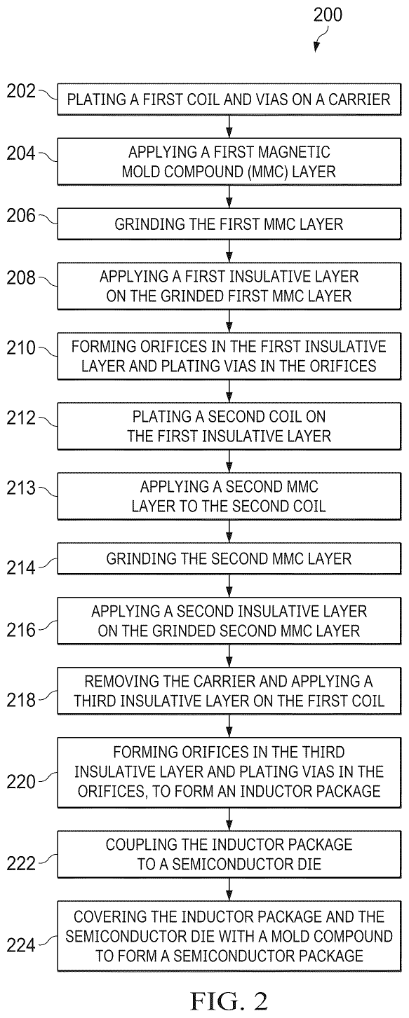

FIGS. 1A1-1L3 are profile, top-down, and perspective views of a process flow for manufacturing a magnetic mold compound (MMC) inductor package having dielectric layers, in accordance with various examples. FIG. 2 is a flow diagram of a method 200 for manufacturing a semiconductor package including an MMC inductor package having dielectric layers, in accordance with various examples. Accordingly, FIGS. 1A1-1L2 and 2 are now described in parallel with each other.

The method 200 begins with plating a first coil and vias on a carrier (202). FIG. 1A1 depicts a profile, cross-sectional view of a carrier 100 on which a coil 102 is plated (e.g., by electroplating or electroless plating). The carrier 100 may include any suitable material, such as plastic, quartz, or ceramic, which offer properties such as chemical inertness, thermal stability, and mechanical strength. The coil 102 may include any suitable type of conductive material, such as a suitable metal or metal alloy (e.g., copper, aluminum, silver, gold, ferrite-based alloys). The coil 102 may have any suitable number of windings, irrespective of the specific number of windings shown in the drawings of this disclosure. The physical dimensions of the coil 102 may be of any suitable size. In addition to the coil 102, vias 104 and 106 are plated on specific portions of the coil 102. For example, the via 104 may be plated on an outermost segment of the coil 102, such as a first end of the coil 102. The via 106 may be plated on an innermost segment of the coil 102, such as a center of the coil 102. As described in greater detail below, the vias 104 and 106 may be useful to form conductive terminals that enable a semiconductor die or other device to provide electrical energy to the inductor of which the coil 102 is a part. FIG. 1A2 is a top-down view of the structure of FIG. 1A1, in accordance with various examples. FIG. 1A3 is a perspective view of the structure of FIG. 1A1, in accordance with various examples.

The method 200 includes applying a first MMC layer to the structure formed by step 202 (204). An MMC may include various components such as iron, which has a high magnetic permeability; ferrites, which may include iron oxide and/or other metal oxides, such as manganese, nickel, or zinc; and amorphous or nanocrystalline alloys, such as iron-silicon-boron, or iron-nickel, which exhibit desirable magnetic properties, including high permeability and low core losses. Further, the MMC layer may include non-magnetic binders, such as polymer resins, which are useful to hold the magnetic powder particles together to form a cohesive structure and may include epoxy, phenolic, polyamide, and polyester resins. The MMC layer also may include non-magnetic fillers and additives to adjust properties such as viscosity, thermal conductivity, and mechanical strength. Various processing aids also may be included in the MMC, such as solvents, dispersants, and/or curing agents. FIG. 1B1 is a profile, cross-sectional view of the structure of FIG. 1A1, except with the application of an MMC layer 108 comprising iron ions 110. The depiction of the iron ions 110 is illustrative; in examples, the specific number, size, distribution, and other properties of the iron ions 110 may vary. The MMC layers described herein, such as the MMC layer 108, are a mold compound with metal (e.g., iron) particles distributed throughout the mold compound (which is distinguishable from a mold compound with a singular magnetic core). FIG. 1B2 is a top-down view of the structure of FIG. 1B1, in accordance with various examples. FIG. 1B3 is a perspective view of the structure of FIG. 1B1, in accordance with various examples.

The method 200 includes grinding the first MMC layer to thin the first MMC layer (206). The first MMC layer is thinned to remove excess thickness of the first MMC layer, such that the top surfaces of the underlying vias 104, 106 are exposed. FIG. 1C1 is a profile, cross-sectional view of the structure of FIG. 1B1, except that the MMC layer 108 has been thinned by grinding to expose the top surfaces of the vias 104 and 106, as shown. The resulting structure, shown in FIG. 1C1, has a top surface 112, which includes the vias 104, 106, the MMC layer 108, and one or more iron ions 110. After grinding, the thickness of the MMC layer 108 ranges from 60 microns to 115 microns, with the lower bound representing a manufacturing tolerance limit, and with thicknesses beyond the upper bound adding cost and resulting in reduced coupling and quality factors of the inductor coils. FIG. 1C2 is a top-down view of the structure of FIG. 1C1, in accordance with various examples. FIG. 1C3 is a perspective view of the structure of FIG. 1C1, in accordance with various examples.

The method 200 includes applying a first insulative layer on the grinded first MMC layer (208). FIG. 1D1 is a profile, cross-sectional view of the structure of FIG. 1C1, with the addition of an insulative layer 114 on the top surface 112. The insulative layer 114 may be a dielectric layer such as silicon dioxide, silicon nitride, polyimide, epoxy resins, benzocyclobutene, fluoropolymers, or another suitable type of material, such as an organic polymer (e.g., polyethylene, polypropylene, polyethylene terephthalate). The dielectric may comprise solder resist, prepreg, or build-up film (e.g., AJINOMOTO® build-up film). The thickness of the insulative layer 114 ranges from 10 microns to 40 microns, with the lower bound of this range being critical because manufacturing tolerances do not allow for thicknesses below this range, and with the upper bound of this range being critical because thicknesses above this range result in reduced coupling and quality factors of the inductor coils. The insulative layer 114 covers all areas of the top surface 112 to ensure that short circuits between the various conductive features of the package being formed in FIGS. 1A1-1L3 are not inadvertently established. FIG. 1D2 is a top-down view of the structure of FIG. 1D1, in accordance with various examples. FIG. 1D3 is a perspective view of the structure of FIG. 1D1, in accordance with various examples.

The method 200 includes forming orifices in the first insulative layer and plating vias in the orifices (210). FIG. 1E1 is a profile, cross-sectional view of the structure of FIG. 1D1, except that orifices 116 are formed in the insulative layer 114. For example, the orifices 116 are formed in vertical alignment with the vias 104, 106, meaning that a vertical line extends through the centers of the via 104 and a respective one of the orifices 116, and that another vertical line extends through the centers of the via 106 and the other one of the orifices 116. The orifices 116 must not expose any of the MMC layer 108, as doing so can cause inadvertent shorting of the type described in detail above. The orifices 116 expose the top surfaces of the vias 104, 106 such that the vias 104, 106 are freely accessible through the orifices 116, as shown. FIG. 1E2 is a top-down view of the structure of FIG. 1E1, in accordance with various examples. FIG. 1E3 is a perspective view of the structure of FIG. 1E1, in accordance with various examples.

FIG. 1F1 is a profile, cross-sectional view of the structure of FIG. 1E1, except that vias 117, 118 are plated in the orifices 116 that were formed over the respective vias 104, 106. The vias 117, 118 may be formed by electroplating or electroless plating, or by any other suitable technique. The vias 117, 118 fill their respective orifices 116, as shown. In examples, the top surfaces of the vias 117, 118 and the top surface of the insulative layer 114 are all approximately flush (i.e., within +/−5 microns) with each other. The vias 117, 118 may be composed of any suitable metal or alloy, such as copper, gold, or silver. FIG. 1F2 is a top-down view of the structure of FIG. 1F1, in accordance with various examples. FIG. 1F3 is a perspective view of the structure of FIG. 1F1, in accordance with various examples.

The method 200 includes plating a second coil on the first insulative layer (212). FIG. 1G1 is a profile, cross-sectional view of the structure of FIG. 1F1, except with the addition of a coil 124 on the insulative layer 114, as shown. The coil 124 may have any number of turns and may be composed of any suitable material. The description provided above for the coil 102 also applies to the coil 124, although the coils 102 and 124 do not necessarily share any physical dimensions, material compositions, locations, etc. The coil 124 may be formed by electroplating, electroless plating, or any other suitable technique. FIG. 1G2 is a top-down view of the structure of FIG. 1G1, in accordance with various examples. FIG. 1G3 is a perspective view of the structure of FIG. 1G1, in accordance with various examples.

The method 200 comprises applying a second MMC layer to the second coil (213). FIG. 1H1 is a profile, cross-sectional view of the structure of FIG. 1G1, except with the addition of an MMC layer 126 containing multiple iron ions 128. The description provided above for the MMC layer 108 also applies to the MMC layer 126, although the MMC layers 108 and 126 need not be identical or have any shared properties. FIG. 1H2 is a top-down view of the structure of FIG. 1H1, in accordance with various examples. FIG. 1H3 is a perspective view of the structure of FIG. 1H1, in accordance with various examples.

The method 200 includes grinding the second MMC layer (214). FIG. 1I1 is a profile, cross-sectional view of the structure of FIG. 1H1, except that the MMC layer 126 has been thinned by grinding. The grinding exposes the top surfaces of the coil 124, and exposes top surfaces of the iron ions 128. The structure of FIG. 111 has a top surface 130 to which the coil 124, at least one of the iron ions 128, and the MMC layer 126 are exposed, as shown. The thickness of the grinded MMC layer 126 ranges from 60 microns to 115 microns, with the lower bound of this range representing a manufacturing tolerance limit, and with thicknesses above this range being disadvantageous because of increased cost and a reduction in coupling and quality factors of the inductor coils. FIG. 112 is a top-down view of the structure of FIG. 111, in accordance with various examples. FIG. 113 is a perspective view of the structure of FIG. 111, in accordance with various examples.

The method 200 comprises applying a second insulative layer on the grinded second MMC layer (216). FIG. 1J1 is a profile, cross-sectional view of the structure of FIG. 111, except with the addition of an insulative layer 132 on the top surface 130. The insulative layer 132 has a thickness ranging from 10 microns to 40 microns, with thicknesses below this range being difficult or impossible due to manufacturing tolerances, and with thicknesses above this range being disadvantageous because of increased cost, without any performance advantage. The description of the material composition of the insulative layer 114 provided above also applies to the insulative layer 132, although the insulative layers 114, 132 do not necessarily share any properties. FIG. 1J2 is a top-down view of the structure of FIG. 1J1, in accordance with various examples. FIG. 1J3 is a perspective view of the structure of FIG. 1J1, in accordance with various examples.

The method 200 includes removing the carrier and applying a third insulative layer on the first coil (218). The method 200 also comprises forming orifices in the third insulative layer and plating vias in the orifices, thereby forming an inductor package (220). FIG. 1K1 is a profile, cross-sectional view of the structure of FIG. 1J1, except that the carrier 100 has been removed, the structure has been rotated in the vertical plane by 180 degrees (i.e., turned upside down), and a third insulative layer 133 is applied to the coil 102 and the MMC layer 108, as shown. The description provided above for the first and second insulative layers 114, 132 also applies to the third insulative layer 133, but the insulative layers 114, 132, 133 do not necessarily share the same properties, such as physical dimensions, material compositions, etc. The third insulative layer 133 has a thickness ranging from 10 microns to 40 microns, with a thickness above this range being disadvantageous because of increased cost without any performance advantage, and with a thickness below this range being disadvantageous because of manufacturing tolerance limitations. Orifices 134 are formed in the third insulative layer 133, in vertical alignment with the via 104 and a segment of the coil 102 closest to the via 104, as shown, meaning that a vertical line extends through the via 104 and one of the orifices 134, and another vertical line extends through the segment of the coil 102 closest to the via 104 and the other one of the orifices 134. As with the orifices 116, the orifices 134 expose the coil 102 such that the coil 102 is directly accessible through the orifices 134, but the orifices 134 must not allow the MMC layer 108 to be exposed, as this raises the risk of the inadvertent electrical shorting described above. FIG. 1K2 is a top-down view of the structure of FIG. 1K1, in accordance with various examples. FIG. 1K3 is a perspective view of the structure of FIG. 1K1, in accordance with various examples.

FIG. 1L1 is a profile, cross-sectional view of the structure of FIG. 1K1, except that the orifices 134 are filled with plated (e.g., by electroplating or by electroless plating) vias 136 and 138. The vias 136, 138 may be composed of any suitable metal or alloy, such as copper, gold, or silver. In examples, the top surfaces of the vias 136, 138 and the top surface of the third insulative layer 133 are all approximately flush (i.e., within +/−5 microns) with each other. Taken together, the vias 104, 117, and 136 may be referred to herein as vias 142. Taken together, the vias 106, 118 may be referred to herein as vias 140. FIG. 1L2 is a top-down view of the structure of FIG. 1L1, in accordance with various examples. FIG. 1L3 is a perspective view of the structure of FIG. 1L1, in accordance with various examples.

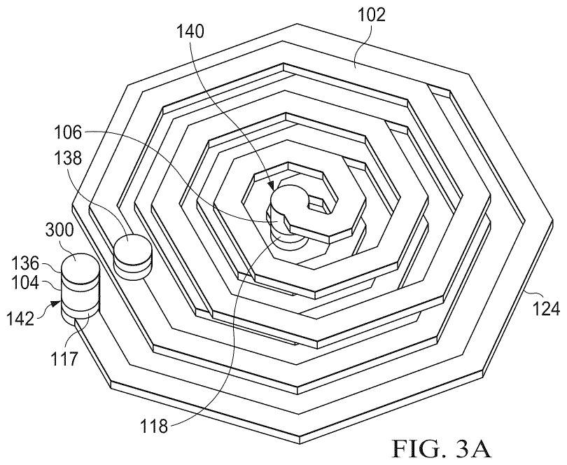

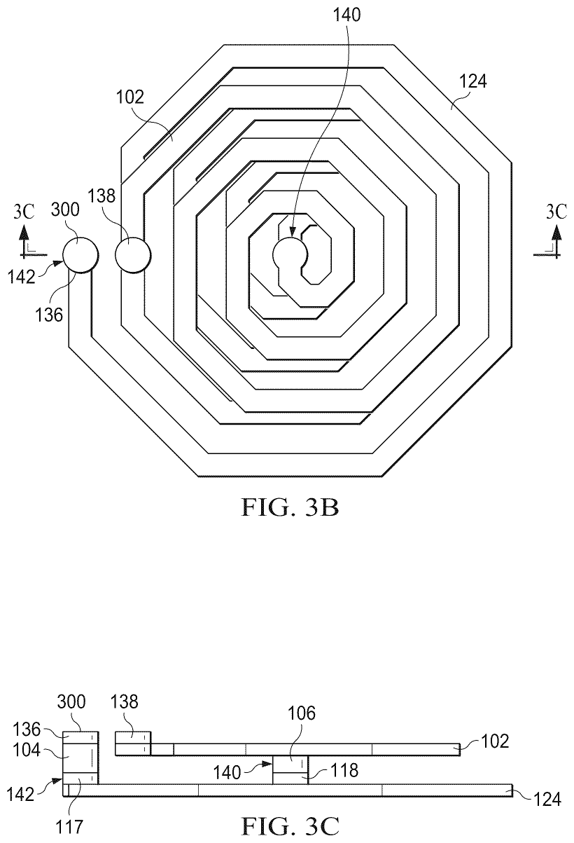

FIG. 3A is a perspective view of the coils 102, 124 and the vias 140, 142. The coils 102 and 124 are in different horizontal planes, meaning that the coils 102 and 124 are vertically separated from each other. Although the coils 102, 124 are represented as being rectangular, other shapes, such as circular coils, are also contemplated and included in the scope of this disclosure. Via 138 couples to a first end of the coil 102 and extends vertically from the horizontal plane of the coil 102. A second end of the coil 102 is in the center of the coil 102 and is coupled to the via 140, which extends vertically downward toward the coil 124. The via 140 is coupled to a first end of the coil 124, and a second end of the coil 124 is coupled to the via 142. The via 142 extends vertically toward the horizontal plane of the coil 102. The via 142 has a distal tip 300. The top surface of via 138 is approximately co-planar (i.e., within +/−5 microns) with the distal tip 300. Stated another way, the top surface of via 138 and the distal tip 300 are approximately equidistant from the coil 102. FIG. 3B is a top-down view of the structure of FIG. 3A, in accordance with various examples. FIG. 3C is a profile view of the structure of FIG. 3A, in accordance with various examples.

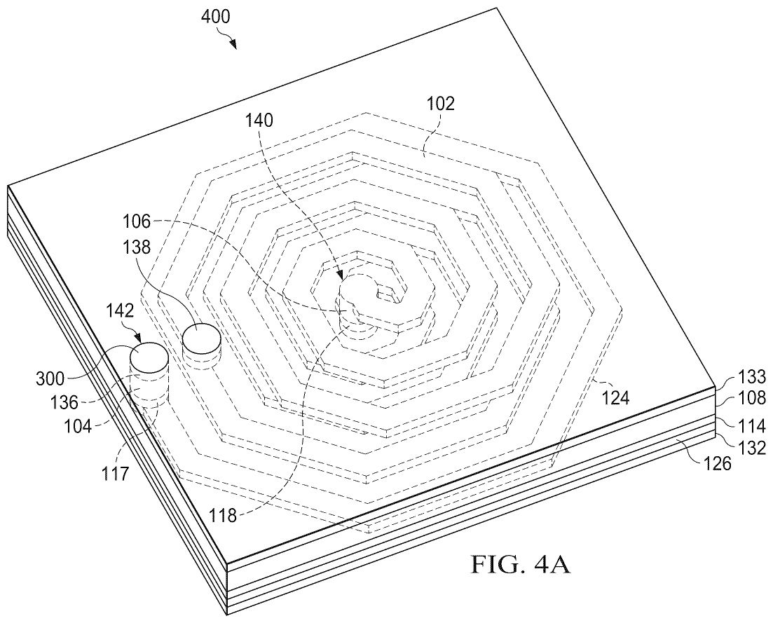

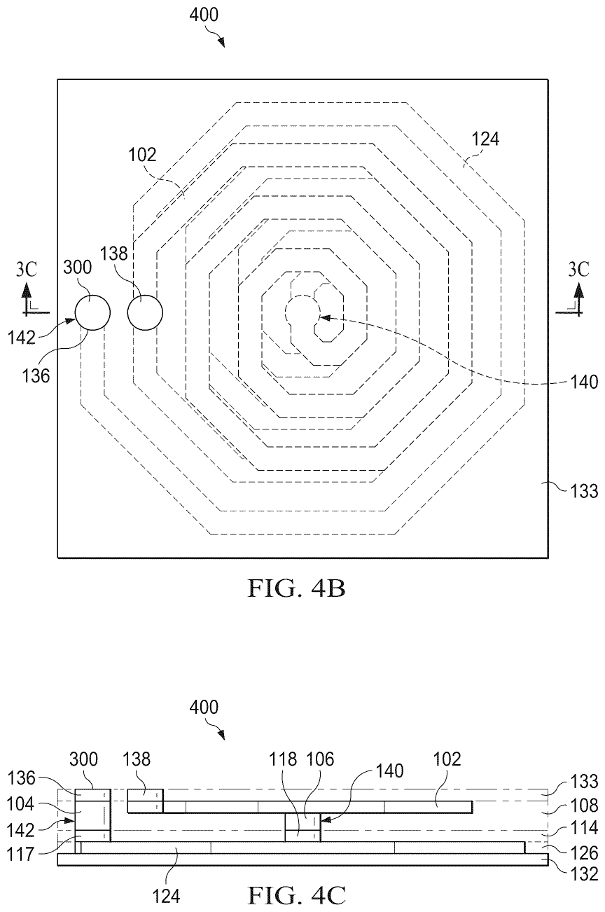

FIG. 4A is a perspective view of an inductor package 400 formed by the method 200 and the process flow of FIGS. 1A1-1L3, in accordance with various examples. FIG. 4B is a top-down view of the structure of FIG. 4A, in accordance with various examples. FIG. 4C is a profile view of the structure of FIG. 4A, in accordance with various examples.

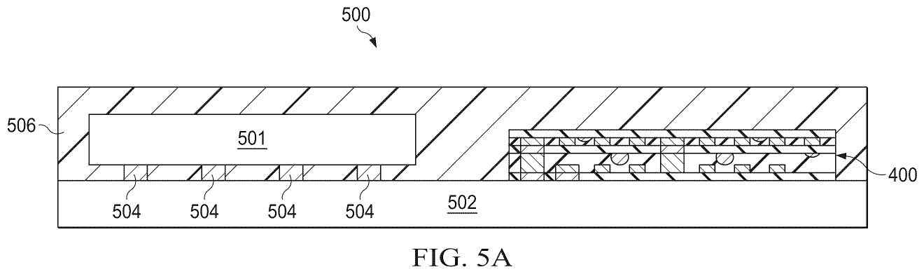

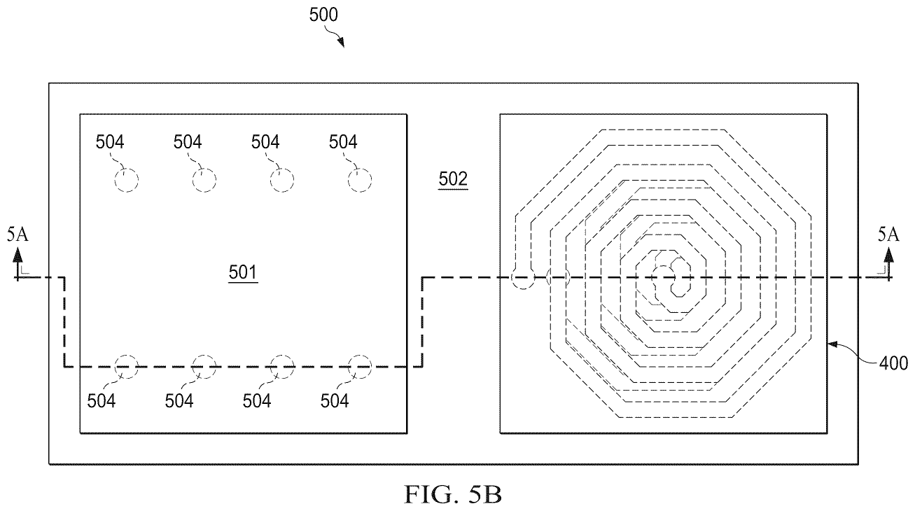

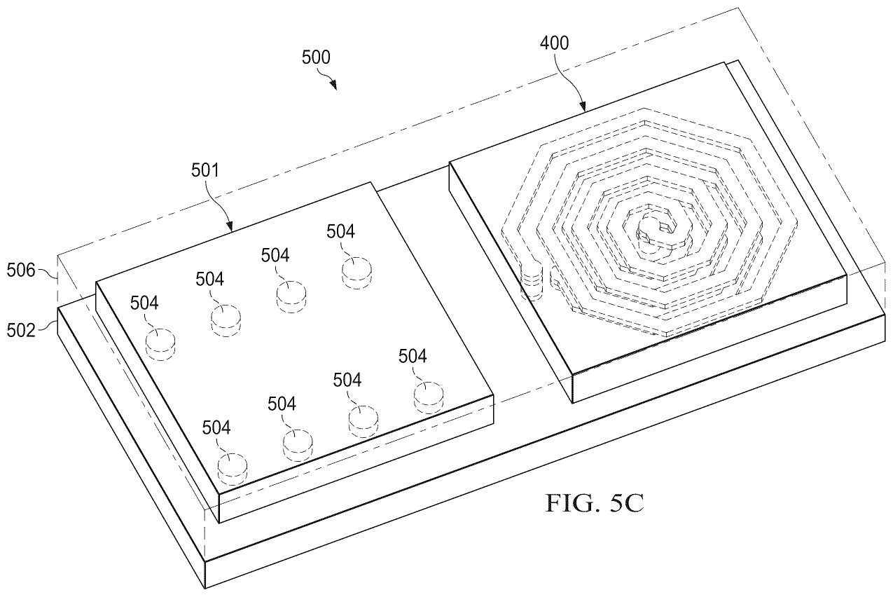

Referring again to the method 200 of FIG. 2, the method 200 includes coupling the inductor package to a semiconductor die (222) and covering the inductor package and the semiconductor die with a mold compound to form a semiconductor package (224). FIG. 5A is a profile, cross-sectional view of a semiconductor package 500 including a semiconductor die 501 coupled to a substrate 502 by way of conductive terminals 504 (e.g., solder bumps). For example, the conductive terminals 504 may be coupled to conductive traces on the substrate 502. The inductor package 400 is coupled to the substrate 502, such as to the conductive traces described above. In this manner, the semiconductor die 501 and the inductor package 400 are coupled to each other, such that the semiconductor die 501 is configured to use the inductor package 400. A mold compound 506 covers the semiconductor die 501, conductive terminals 504, substrate 502, and the inductor package 400. The mold compound 506 does not directly contact any of the coils within the inductor package 400, at least because the insulative layers (e.g., insulative layers 114, 132, 133, such as the dielectric layers) described above prevent such direct contact. FIG. 5B is a top-down view of the structure of FIG. 5A, in accordance with various examples. FIG. 5C is a perspective view of the structure of FIG. 5A, in accordance with various examples.

Although the method 200 depicts the formation of two layers in the inductor package 400, the scope of this disclosure is not limited as such. The method 200 may be expanded to manufacture inductor packages 400 with any suitable number of layers, ranging from one layer and upward.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A semiconductor package, comprising:
a semiconductor die; and
an inductor coupled to the semiconductor die, the inductor comprising:
a first metal coil having a first end coupled to the semiconductor die and a second end;
a second metal coil vertically spaced from the first metal coil and having a third end coupled to the second end and a fourth end coupled to the semiconductor die;
a magnetic mold compound (MMC) between the first and second metal coils, the MMC including conductive ions; and
an insulative layer between the first and metal coils.

2. The package of claim 1, wherein the insulative layer insulates first and second portions of the second metal coil from coming into electrical contact with each other by way of at least one of the conductive ions of the MMC.

3. The package of claim 1, wherein the conductive ions are iron ions.

4. The package of claim 1, wherein the insulative layer is a dielectric layer.

5. The package of claim 4, wherein the dielectric layer is selected from the group consisting of solder resist, prepreg, polyimide, and build-up film.

6. The package of claim 1, wherein the insulative layer includes an orifice through which the first and second metal coils couple to each other.

7. The package of claim 1, wherein the insulative layer has a thickness ranging from 10 microns to 40 microns.

8. The package of claim 1, wherein the inductor is coupled to the semiconductor die by way of conductive layers in a substrate of the package.

9. A semiconductor package, comprising:
an inductor, comprising:
a first metal coil having first and second ends, the first end accessible to a device outside of the inductor;
a second metal coil having third and fourth ends;
a magnetic mold compound (MMC) between the first and second metal coils;
a dielectric layer between the first and second metal coils, the dielectric layer contacting the first coil and not contacting the second coil;
a first via coupling the second and third ends through a first orifice in the dielectric layer; and
a second via coupled to the fourth end and extending vertically through a second orifice in the dielectric layer to terminate at a fifth end, the first and fifth ends approximately equidistant from the first coil in the vertical direction.

10. The package of claim 9, further comprising a semiconductor die coupled to the first and fifth ends, and a mold compound covering the semiconductor die and the inductor.

11. The package of claim 9, further comprising a second dielectric layer, the first metal coil between the first and second dielectric layers.

12. The package of claim 9, wherein the MMC includes iron ions.

13. A method for manufacturing a semiconductor package, comprising:
plating a first metal coil on a carrier;
covering the first metal coil with a first magnetic mold compound (MMC) layer;
grinding the first MMC layer to reduce a thickness of the first MMC layer;
covering the first MMC layer with an insulative layer having a thickness ranging from 10 microns to 40 microns;
forming first and second orifices in the insulative layer;
plating a second metal coil on a first surface of the insulative layer opposite a second surface of the insulative layer facing the first metal coil, the first and second metal coils coupled by a via extending through the first orifice;
covering the second metal coil with a second MMC layer;
grinding the second MMC layer to reduce a thickness of the second MMC layer;
removing the carrier;
coupling a semiconductor die to the first and second metal coils; and
covering the semiconductor die and the first and second metal coils with a mold compound.

14. The method of claim 13, further comprising:
forming a second via extending vertically from the second metal coil toward the first metal coil;
forming a third via extending vertically away from the first metal coil, wherein a first end of the second via and a second end of the third via are approximately equidistant from the first metal coil.

15. The method of claim 13, wherein the MMC layer comprises conductive ions.

16. The method of claim 15, wherein the conductive ions include iron ions.

17. The method of claim 13, wherein the insulative layer is a dielectric layer.

18. The method of claim 17, wherein the dielectric layer is selected from the group consisting of solder resist, prepreg, polyimide, and build-up film.

19. The method of claim 13, wherein the mold compound does not directly contact the second metal coil.

20. The method of claim 13, further comprising covering the second MMC layer with a second dielectric layer.
